(19) United States
(12) Patent Application Publication
(10) Pub. No.: US 2009/0302958 A1
(43) Pub. Date: Dec. 10, 2009

(54) DIGITALLY CONTROLLED OSCILLATOR AND PHASE LOCKED LOOP CIRCUIT USING THE DIGITALLY CONTROLLED OSCILLATOR

(75) Inventors: Hiroki Sakurai, Fuchu-shi (JP); Osamu Watanabe, Chigasaki-shi (JP); Shoji Otaka, Yokohama-shi (JP); Ryoichi Tachibana, Kawasaki-shi (JP)

Correspondence Address: Charles N.J. Ruggiero, Esq.;Ohlandt, Greeley, Ruggiero & Perle, L.L.P., 10th Floor, One Landmark Square, Stamford, CT, 06901-2682, US

(73) Assignee: KABUSHIKI KAISHA TOSHIBA

(21) Appl. No.: 12/408,910

(22) Filed: Mar. 23, 2009

(30) Foreign Application Priority Data
Jun. 5, 2008 (JP) 2008-148435

(51) Int. Cl. H03L 7/099

(52) U.S. Cl. 331/1 A

(57) ABSTRACT

A digitally controlled oscillator includes a differential inductor including a positive terminal which outputs a positive-phase oscillation signal, a negative terminal which outputs a negative-phase oscillation signal, and a center tap, and including a first contact point in an arbitrary position between the positive terminal and the center tap, and a second contact point in a position corresponding to the first contact point between the negative terminal and the center tap, a first variable capacitor bank connected between the positive terminal and the negative terminal and including a plurality of first variable capacitors which switch capacitance between two values according to a first digital control code, and a second variable capacitor bank connected between the first contact point and the second contact point and including a plurality of second variable capacitors which switch capacitance between two values according to a second digital control code.

### CROSS-REFERENCE TO RELATED APPLICATIONS

This application is based upon and claims the benefit of priority from prior Japanese Patent Application No. 2008-148435, filed Jun. 5, 2008, the entire contents of which are incorporated herein by reference.

### BACKGROUND OF THE INVENTION

1. Field of the Invention

The present invention relates to improvement of frequency resolution in a digitally controlled oscillator and a phase locked loop circuit using the digitally controlled oscillator.

2. Description of the Related Art

A radio transceiver represented by a cellular phone (a) upconverts a transmitting baseband signal using a local signal to transmit a radio signal via an antenna, and (b) downconverts the radio signal received via the antenna to obtain a received baseband signal. The upconversion and the downconversion require a frequency converter for converting frequencies and a local oscillator for generating local signals.

Recently, a digitally controlled oscillator (DCO) capable of discretely controlling an oscillation frequency by means of digital control codes (digital control signals) has been proposed as a local oscillator. The DCO is configured to discretely switch an oscillation frequency by means of digital control codes, and thereby quantization noise occurs in the oscillation frequency. The greater the quantization noise, the gap between the oscillation frequency and a desired frequency increases, and the carrier to noise ratio (CNR) is deteriorated. In order to reduce the quantization noise in the oscillation frequency, the frequency resolution of the DCO must be improved. That is, the control of the oscillation frequency of the DCO by means of digital control codes must be implemented more finely. Usually, the DCO has a variable capacitor connected in parallel to an inductor or a transmission line, and control of the oscillation frequency can be implemented by varying the capacitance of the variable capacitor by means of digital control codes. Therefore, the capacitance resolution of the variable capacitor determines the frequency resolution of the DCO.

In the DCO disclosed in “Fine and Wide Frequency Tuning Digital Controlled Oscillators Utilizing Capacitance Position Sensitivity in Distributed Resonators”, ASSCC 2007, pp. 424-427 (hereinafter simply referred to as Related Art 1), variable capacitors are connected in parallel to a transmission line in a plurality of positions on the transmission line. In the DCO disclosed in Related Art 1, the effect caused by the capacitance of the variable capacitors on the transmission line on the oscillation frequency of the DCO varies according to the positions in which the variable capacitors are connected. According to the DCO disclosed in Related Art 1, the effect caused by the capacitance of some of the variable capacitors on the oscillation frequency of the DCO can be reduced, and thereby a higher frequency resolution can be obtained as compared to a configuration in which an inductor or a transmission line and a variable capacitor is simply connected in parallel.

In the DCO disclosed in Related Art 1, however, since the connection positions of the variable capacitors are different from one another, the effect caused by each of the variable capacitors on the oscillation frequency is not uniform. That is, it is difficult to cause the digital control codes to linearly change the oscillation frequency of the DCO.

### BRIEF SUMMARY OF THE INVENTION

According to an aspect of the invention, there is provided a digitally controlled oscillator comprising: a differential inductor including a positive terminal which outputs a positive-phase oscillation signal, a negative terminal which outputs a negative-phase oscillation signal, and a center tap, and including a first contact point in an arbitrary position between the positive terminal and the center tap, and a second contact point in a position corresponding to the first contact point between the negative terminal and the center tap; a first variable capacitor bank connected between the positive terminal and the negative terminal and including a plurality of first variable capacitors which switch capacitance between two values by means of a first digital control code; a second variable capacitor bank connected between the first contact point and the second contact point and including a plurality of second variable capacitors which switch capacitance between two values by means of a second digital control code; and a negative resistor connected between the positive terminal and the negative terminal.

According to another aspect of the invention, there is provided a digitally controlled oscillator comprising: an inductor pair formed by shorting one end of a first inductor and one end of a second inductor, configured to output a positive-phase oscillation signal from the other end of the first inductor and output a negative-phase oscillation signal from the other end of the second inductor, and including a first contact point in an arbitrary position of the first inductor and a second contact point in a position corresponding to the first contact point of the second inductor; a first variable capacitor bank connected between the other end of the first inductor and the other end of the second inductor and including a plurality of first variable capacitors which switch capacitance between two values by a first digital control code; a second variable capacitor bank connected between the first contact point and the second contact point and including a plurality of second variable capacitors which switch capacitance between two values by a second control code; and a negative resistor connected between the other end of the first inductor and the other end of the second inductor.

### BRIEF DESCRIPTION OF THE SEVERAL VIEWS OF THE DRAWING

FIG. 1 is a block diagram showing a digitally controlled oscillator according to a first embodiment.

FIG. 2 is a block diagram showing a differential digitally controlled oscillator corresponding to FIG. 1.

FIG. 3 is a block diagram showing a configuration example of the differential digitally controlled oscillator of FIG. 2.

FIG. 4 is a graph showing frequency resolution of the differential digitally controlled oscillator of FIG. 3.

FIG. 5 is a block diagram showing a differential digitally controlled oscillator according to a second embodiment.

FIG. 6 is a graph showing frequency resolution of the differential digitally controlled oscillator of FIG. 5.

FIG. 7 is a block diagram showing a differential digitally controlled oscillator according to a third embodiment.

FIG. 8 is a graph showing frequency resolution of the differential digitally controlled oscillator of FIG. 7.

FIG. 9 is a block diagram showing a differential digitally controlled oscillator according to a fourth embodiment.

FIG. 10 is a graph showing frequency resolution of the differential digitally controlled oscillator of FIG. 9.

FIG. 11 is a block diagram showing a differential digitally controlled oscillator according to a fifth embodiment.

FIG. 12 is a block diagram showing a differential digitally controlled oscillator according to a sixth embodiment.

FIG. 13A shows an example of a variable capacitor bank.

FIG. 13B shows an example of a variable capacitor bank.

FIG. 14 is a block diagram showing a digital phase locked loop circuit according to a seventh embodiment.

### DETAILED DESCRIPTION OF THE INVENTION

Hereinafter, embodiments of the present invention will now be described with reference to the accompanying drawings.

### First Embodiment

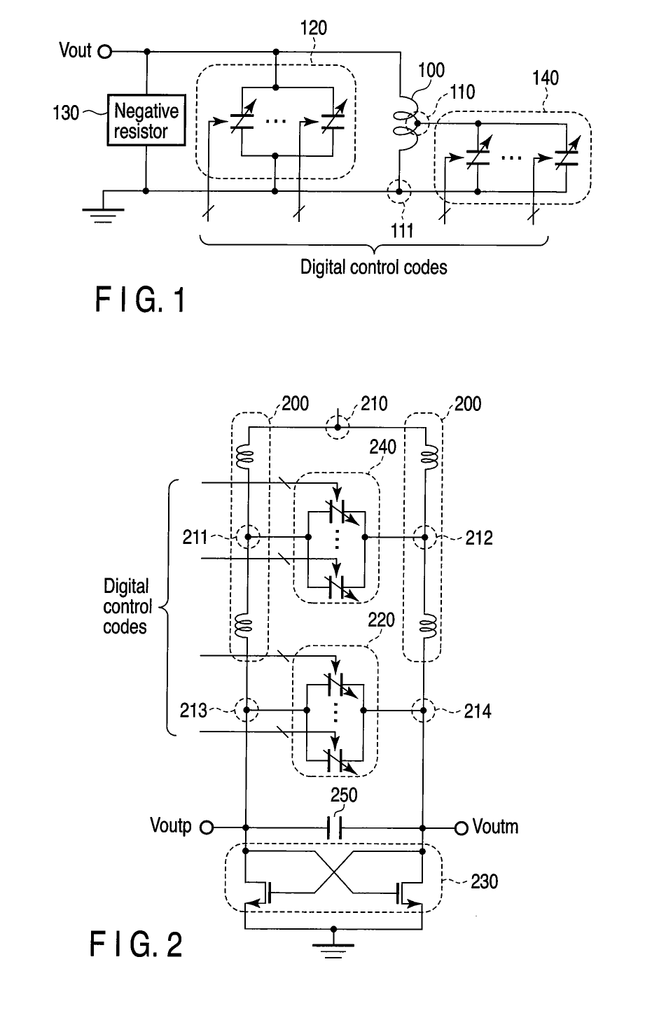

As shown in FIG. 1, a digitally controlled oscillator according to a first embodiment of the present invention includes an inductor 100, a coarse tuning variable capacitor bank 120, a negative resistor 130, and a fine tuning variable capacitor bank 140.

One end of the inductor 100 is connected to an output terminal Vout and the other end 111 is grounded. One end of the coarse tuning variable capacitor bank 120 and one end of the negative resistor 130 are commonly connected to the one end of the inductor 100. The inductor 100 has a contact point 110 between the one end and the other end 111, and one end of the fine tuning capacitor bank 140 is connected to the contact point 110. The other end of the coarse tuning variable capacitor bank 120, the other end of the negative resistor 130, and the other end of the fine tuning variable capacitor bank 140 are commonly connected to the other end 111 of the inductor 100.

The coarse tuning variable capacitor bank 120 is provided to coarsely tune the oscillation frequency of the DCO of FIG. 1, and its capacitance is controlled by digital control codes. The coarse tuning variable capacitor bank 120 and the fine tuning variable capacitor bank 140, which will be described later, are fabricated by connecting in parallel a plurality of variable capacitors formed of capacitors connected to switches, for example, and control on/off of each of the switches by digital control codes to switch the capacitance of each of the variable capacitors between two values (on/off) to change the overall capacitance. The coarse tuning variable capacitor bank 120 and the fine tuning variable capacitor bank 140 may be fabricated by connecting in parallel a plurality of variable capacitors using a gate capacitor of a MOS transistor, for example, and the capacitance of each of the variable capacitors may be switched between the two values by digital control codes to change the overall capacitance.

The capacitance resolution of each of the coarse tuning variable capacitor bank 120 and the fine tuning variable capacitor bank 140 is determined by the capacitance variation of each of the variable capacitors forming each of the coarse tuning variable capacitor bank 120 and the fine tuning variable capacitor bank 140. In general, a variable capacitor using a gate capacitor of a MOS transistor can make the capacitance variation small, compared to a variable capacitor formed of capacitors connected to switches.

Further, the overall capacitance change range of each of the coarse tuning variable capacitor bank 120 and the fine tuning variable capacitor bank 140 is determined by the bit lengths of the digital control codes and the capacitance resolution. That is, the greater the bit length of the digital control codes, the greater the overall capacitance change range of each of the coarse tuning variable capacitor bank 120 and the fine tuning variable capacitor bank 140.

The negative resistor 130 compensates for loss made by an LC circuit, that is, loss made by the inductor 100, the coarse tuning variable capacitor bank 120, and the fine tuning variable capacitor bank 140, and maintains oscillation of the DCO shown in FIG. 1. The negative resistor 130 is formed of a positive feedback amplifier, for example.

The fine tuning variable capacitor bank 140 is connected between the contact point 110, provided between the one end and the other end 111 of the inductor 100, and the other end 111 of the inductor 100, as described above. The fine tuning variable capacitor bank 140 is provided to finely tune the oscillation frequency of the DCO of FIG. 1, and the capacitance is controlled by digital control codes. Here, fine tuning means that the range of adjustment of the oscillation frequency of the fine tuning capacitor bank 140 is narrower than that of the coarse tuning capacitor bank 120 in FIG. 1. It is therefore preferable that the capacitance resolution of the fine tuning variable capacitor bank 140 is higher than that of the coarse tuning variable capacitor bank 120.

Hereinafter, the technical significance that the one end of the fine tuning variable capacitor bank 140 is connected to the contact point 110 provided between the one end of the inductor 100 and the other end 111, instead of being connected to the one end of the inductor 100.

Assuming that the inductance generated between the one end of the inductor 100 and the other end 111 is L1, the inductance generated between the contact point 110 and the other end 111 can be expressed by a*L1. The value a is a constant (0<a<1) determined by the position occupied by the contact point 110 in the inductor 100, and becomes smaller as the position is closer to the other end 111. Assuming that the capacitance of each of the coarse tuning variable capacitor bank 120 and the fine tuning variable capacitor bank 140 is C1 and C2, the oscillation frequency fout of the DCO of FIG. 1 can be expressed by the following expression (linearly approximated expression) (1):

$${f}_{out} = \frac{1}{2 π \sqrt{{L}_{1} ( {C}_{1} + {aC}_{2} )}} \qquad ( 1 )$$

When the one end of the fine tuning variable capacitor bank 140 is connected to the one end of the inductor 100, on the other hand, the oscillation frequency fout′ of the DCO can be expressed by the following expression (linearly approximated expression) (2):

$${f}_{out}^{′} = \frac{1}{2 π \sqrt{{L}_{1} ( {C}_{1} + {C}_{2} )}} \qquad ( 2 )$$

As clear from the comparison between the expression (1) and the expression (2), by connecting the one end of the fine tuning variable capacitor bank 140 to the contact point 110 of the inductor 100, the effect caused by the capacitance C2 on the oscillation frequency fout can be made relatively small. As described above, the constant a becomes smaller as the position of the contact point 110 is brought nearer to the other end of the inductor 110. This will also reduce the effect caused by the capacitance C2 on the oscillation frequency fout.

Assuming that the control signal value corresponding to the digital control code assigned to the coarse tuning variable capacitor bank 120 is N1, the capacitance resolution of the coarse tuning variable capacitor bank 120 is ΔC1, and the capacitance of the coarse tuning variable capacitor bank 120 when all the variable capacitors forming the coarse tuning capacitor bank 120 is set off is C01, the capacitance C1 can be expressed by the following expression (3):

C₁=C₀₁+N₁×ΔC₁ (3)

Assuming that the control signal value corresponding to the digital control code assigned to the fine tuning variable capacitor bank 140 is N2, the capacitance resolution of the fine tuning variable capacitor bank 140 is ΔC2, and the capacitance of the fine tuning variable capacitor bank 140 when all the variable capacitor banks forming the fine tuning variable capacitor bank 140 is set off is C02, the capacitance C2 can be expressed by the following expression (4):

C₂=C₀₂+N₂×ΔC₂ (4)

Substituting the expressions (3) and (4) in the expression (1) yields the following expression (linearly approximated expression) (5):

$${f}_{out} = \frac{1}{2 π \sqrt{{L}_{1} ( {C}_{01} + {N}_{1} \times Δ {C}_{1} + a ( {C}_{02} + {N}_{2} \times Δ {C}_{2} ) )}} \qquad ( 5 )$$

Even if the capacitance resolution ΔC1 of the coarse tuning variable capacitor bank 120 and the capacitance resolution ΔC2 of the fine tuning variable capacitor bank 140 are the same values in the expression (5), since the capacitance resolution ΔC2 is multiplied by the constant a, the capacitance resolution ΔC2 has a lower effect on the oscillation frequency fout than the capacitance resolution ΔC1. That is, the capacitance resolution ΔC2 is substantially higher than the capacitance resolution ΔC1. Further, since the capacitances C1 and C2 lineally change with respect to the control signal values N1 and N2, respectively, the effect of each of the coarse tuning variable capacitor bank 120 and the fine tuning variable capacitor bank 140 on the oscillation frequency fout can be changed approximately lineally with respect to the digital control codes by appropriately determining the capacitance resolutions ΔC1 and ΔC2 and the constant a.

The DCO shown in FIG. 1 can be configured as a differential DCO. The differential DCO according to the present embodiment includes an inductor pair 200, a coarse tuning capacitor bank 220, a negative resistor 230, a fine tuning capacitor bank 240, and a constant capacitor 250, as shown in FIG. 2.

The differential (balanced-type) inductor 200 has a positive terminal 213 and a negative terminal 214, and has a center tap 210 at the approximate center between the positive terminal 213 and the negative terminal 214. Here, the approximate center means that the two-dimensional distance (in which height is not considered) between the center tap 210 and the positive terminal 213 and the two-dimensional distance between the center tap 210 and the negative terminal 214 in the differential inductor 200 are equal. In other words, the inductance generated between the positive terminal 213 and the center tap 210 and the inductance generated between the negative terminal 214 and the center tap 210 are equal. In reality, since the differential inductor 200 includes three-dimensional crossing, the three-dimensional distance between the center tap 210 and the positive terminal 213 and the three-dimensional distance between the center tap 210 and the negative terminal 214 do not necessarily agree.

Further, the differential inductor 200 has a contact point 211 between the center tap 210 and the positive terminal 213 and a contact point 212 between the center tap 210 and the negative terminal 214. The position of each of the contact points 211 and 212 on the differential inductor 200 should preferably be symmetric with respect to the center tap 210. That is, the two-dimensional distance between the center tap 210 and the contact point 211 and the two-dimensional distance between the center tap 210 and the contact point 212 should preferably agree in the differential inductor 200. In other words, the inductance generated between the contact point 211 and the center tap 210 and the inductance generated between the contact point 212 and the center tap 210 should preferably agree.

The positive terminal 213 of the differential inductor 200 is connected to a positive-phase output terminal Voutp, and the negative terminal 214 is connected to a negative-phase output terminal Voutm. Further, the coarse tuning variable capacitor bank 220, the negative resistor 230, and the constant capacitor 250 are connected in parallel to the positive terminal 213 and the negative terminal 214 of the differential inductor 200. The fine tuning variable capacitor bank 220, which will be described below, is connected between the contact point 211 and the contact point 212 in the differential inductor 200. The center tap 210 in the differential inductor 200 is connected to the ground, a power source, or a bias circuit, for example.

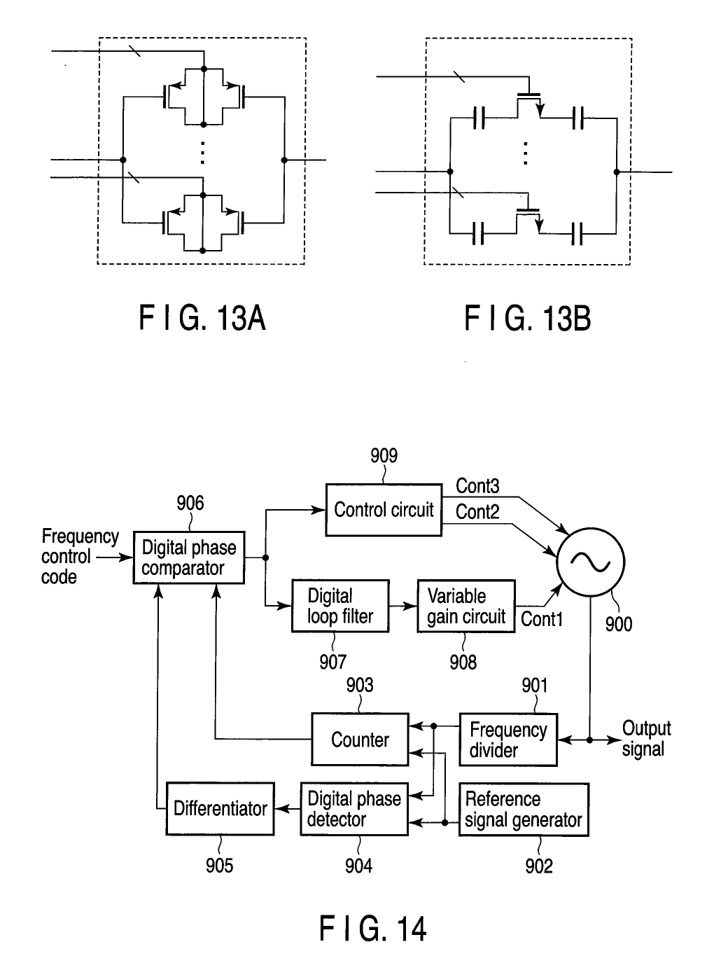

The coarse tuning variable capacitor bank 220 is provided to coarsely tune the oscillation frequency of the DCO of FIG. 2, and its capacitance is controlled by digital control codes. The coarse tuning variable capacitor bank 220 and the fine tuning variable capacitor bank 240 are fabricated by connecting in parallel a plurality of variable capacitors formed of capacitors connected to switches and control on/off of each of the switches by digital control codes by switching the capacitance of each of the variable capacitors between two values (on/off) to change the overall capacitance, as shown in FIG. 13B. Further, the coarse tuning variable capacitor bank 220 and the fine tuning variable capacitor bank 240 may be fabricated by connecting in parallel a plurality of variable capacitors using a gate capacitor of the MOS transistor, as shown in FIG. 13A, and configured to change the overall capacitance by switching the capacitance of each of the variable capacitors between the two values by digital control codes.

The negative resistor 230 compensates for loss made by an LC circuit, that is, loss made by the inductor pair 200, the coarse tuning variable capacitor bank 220 and the fine tuning variable capacitor bank 240 and maintains oscillation by the DCO shown in FIG. 2. The negative resistor 230 is formed of a N-type MOS transistor pair or a P-type MOS transistor pair, for example. More specifically, a negative resistor 230 is fabricated by shorting one drain terminal and the other gate terminal in a common-source MOS transistor pair. The constant capacitor 250 causes a strong effect on the oscillation frequency of the DCO of FIG. 2.

The fine tuning variable capacitor bank 240 is connected between the contact point 211 provided between the positive terminal 213 and the center tap 210 of the inductor pair 200, and the contact point 212 provided between the negative terminal 214 and the center tap 210. The fine tuning variable capacitor bank 240 is provided to finely tune the oscillation frequency of the DCO of FIG. 2, and the capacitance is controlled by digital control codes. In the DCO of FIG. 2, by connecting the fine tuning variable capacitor bank 240 between the contact point 211 and the contact point 212, instead of between the positive terminal 213 and the negative terminal 214 of the inductor pair 200, the effect caused by the fine tuning variable capacitor bank 240 on the oscillation frequency can be made relatively small, and the capacitance resolution of the fine tuning variable capacitor bank 240 is substantially improved, as in the case of the above-described DCO of FIG. 1.

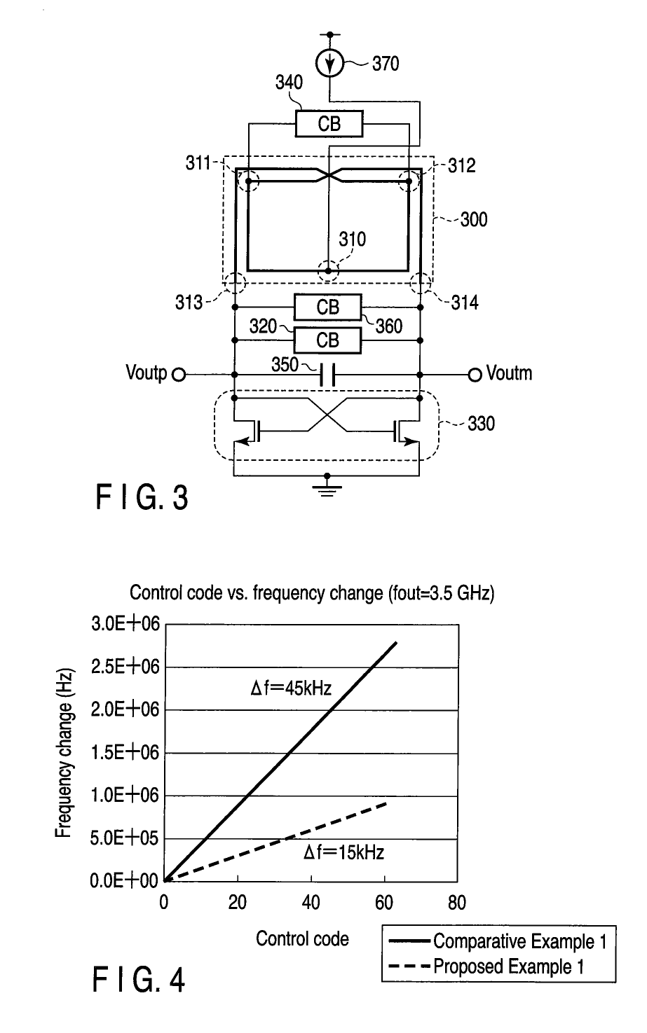

The configuration example of the differential DCO of FIG. 2 is shown in FIG. 3. The differential DCO of FIG. 3 has a differential inductor 300, a coarse tuning variable capacitor bank 320, a negative resistor 330, a fine tuning variable capacitor bank 340, a constant capacitor 350, a middle variable capacitor bank 360, and a bias current source 370.

The number of turns of the differential inductor 300 is 1.75. The differential inductor 300 has a positive terminal 313 and a negative terminal 314, and has a center tap 310 at the approximate center between the positive terminal 313 and the negative terminal 314. Further, the differential inductor 300 has a contact point 311 in a position which internally divides the center tap 310 and the positive terminal 313 into an approximate ratio of 3:4, and a contact point 312 in a position which internally divides the center tap 310 and the negative terminal 314 into an approximate ratio of 3:4.

The positive terminal 313 of the differential inductor 300 is connected to a positive-phase output terminal Voutp, and the negative terminal 314 is connected to the negative-phase output terminal Voutm. Further, the coarse tuning variable capacitor bank 320, the negative resistor 330, the constant capacitor 350, and the middle variable capacitor bank 360 are connected in parallel to the positive terminal 313 and the negative terminal 314 of the differential inductor 300. The fine tuning variable capacitor bank 340 is connected between the contact point 311 and the contact point 312 in the differential inductor 300. The center tap 310 in the differential inductor 300 is connected to the bias current source 370.

The coarse tuning capacitor bank 320 is provided to coarsely tune the oscillation frequency of the DCO of FIG. 3, and its capacitance is controlled by digital control codes. The coarse tuning variable capacitor bank 320 is fabricated by connecting in parallel a plurality of variable capacitors formed of capacitors connected to switches, as shown in FIG. 13B, for example. The overall capacitance is changed by controlling on/off of each of the switches by means of digital control codes to switch the capacitance of each of the variable capacitors between two values (on/off).

The negative resistor 330 compensates for loss made by an LC circuit, that is, loss made by the differential inductor 300, the coarse tuning variable capacitor bank 320, the fine tuning variable capacitor bank 340, and the middle variable capacitor bank 360, and maintains oscillation of the DCO of FIG. 3. The negative resistor 330 is formed of N-type MOS transistor pair or a P-type MOS transistor pair, for example. More specifically, a negative resistor 330 is fabricated by shorting one drain terminal and the other gate terminal in a common-source MOS transistor pair. The constant capacitor 350 causes a strong effect on oscillation frequency of the DCO of FIG. 3.

The fine tuning variable capacitor bank 340 is connected between the contact point 311 provided between the positive terminal 313 and the center tap 310 of the differential inductor 300 and the contact point 312 provided between the negative terminal 314 and the center tap 310, as described above. The fine tuning variable capacitor bank 340 is provided to finely tune the oscillation frequency of the DCO of FIG. 3, and its capacitance is controlled by digital control codes. In the DCO of FIG. 3, by connecting the fine tuning variable capacitor bank 340 between the contact point 311 and the contact point 312, instead of between the positive terminal 313 and the negative terminal 314 of the differential inductor 300, the effect caused by the fine tuning variable capacitor bank 340 on the oscillation frequency is made relatively small, and thereby the capacitance resolution of the fine tuning variable capacitor bank 340 is substantially improved. The fine tuning variable capacitor bank 340 is fabricated by connecting in parallel a plurality of variable capacitors using gate capacitors of MOS transistors, as shown in FIG. 13A, for example, and changes the overall capacitance by switching the capacitance of each of the variable capacitors between two values by digital control codes.

In order to reduce the effect caused by parasitic elements generated in line which connects the differential inductor 300 and the fine tuning capacitor bank 340, the length of the line should preferably be made as small as possible. Therefore, as shown in FIG. 3, a differential inductor 300 is arranged being interposed between the fine tuning variable capacitor bank 340 and the middle variable capacitor bank 360. Further, the line shape between one end of the fine tuning variable capacitor bank 340 and the contact point 311 of the differential inductor 300 and the line shape between the other end of the fine tuning variable capacitor bank 340 and the contact point 312 of the differential inductor 300 should preferably be symmetrical.

The middle variable capacitor bank 360 is provided to adjust the oscillation frequency of the DCO of FIG. 3, and its capacitance is controlled by digital control codes. The capacitance resolution of the middle variable capacitor bank 360 is higher than the coarse tuning variable capacitor bank 320, and lower than the fine tuning variable capacitor bank 340. That is, the middle variable capacitor bank 360 is provided to compensate for the gap between the range of oscillating frequencies adjusted by the coarse tuning variable capacitor bank 320 and the range of oscillating frequencies adjusted by the fine tuning variable capacitor bank 340. The middle variable capacitor bank 360 is fabricated by connecting in parallel a plurality of variable capacitors using gate capacitors of MOS transistors, as shown in FIG. 13A, for example, and changes the overall capacitance by switching the capacitance of each of the variable capacitors between two values by digital control codes.

Hereinafter, the frequency resolution of the DCO of FIG. 3 will be described with reference to the graph shown in FIG. 4. In FIG. 4, the DCO of FIG. 3 is referred to as Proposed Example 1, and the DCO, which is similarly configured except for the change of the connection position of the fine tuning variable capacitor bank 340 of the DCO of FIG. 3 from the position between the contact point 311 and the contact point 312 of the differential inductor 300 to the position between the positive terminal 313 and the negative terminal 314, is referred to as Comparative Example 1. Each of the variable capacitor banks forming the DCO of each of Proposed Example 1 and Comparative Example 1 is controlled by digital control codes of 6 bits (0-63). FIG. 4 illustrates the frequency change of the DCO of each of Proposed Example 1 and Comparative Example 1 with reference to the oscillation frequency fout of 3.5 GHz versus change of the digital control codes. In FIG. 4, the frequency change of the oscillation frequency fout of the DCO of Proposed Example 1 is indicated by the dashed line, and the frequency change of the oscillation frequency fout of the DCO of Comparative Example 1 is indicated by the solid line.

As clear from FIG. 4, the DCO of Proposed Example 1 has a higher frequency resolution than that of the DCO of the Comparative Example 1. More specifically, the frequency resolution Δf of the DCO of Comparative Example 1 is 45 kHz, while the frequency resolution Δf of the DCO of Proposed Example 1 is 15 kHz. The frequency change range of the oscillation frequency of the DCO of Comparative Example 1 is approximately 2.9 MHz (64×45 kHz), and the frequency change range of the oscillation frequency of the DCO of Proposed Example 1 is approximately 1.0 MHz (=64×15 kHz).

As described above, in the DCO according to the present embodiment, the fine tuning variable capacitor bank is connected between the contact points provided between the positive terminal and the negative terminal and a center tap, instead of between a positive terminal and a negative terminal of a differential inductor. According to the DCO of the present embodiment, it is therefore possible to make the effect caused by the capacitance change of the fine tuning variable capacitor bank on the oscillation frequency relatively small, and thereby the frequency resolution of the oscillation frequency is improved. Further, in the DCO according to the present embodiment, since variable capacitors forming each of the variable capacitor banks are connected in the same position to the inductor, and change of the oscillation frequency versus the digital control codes can be made almost lineally.

### Second Embodiment

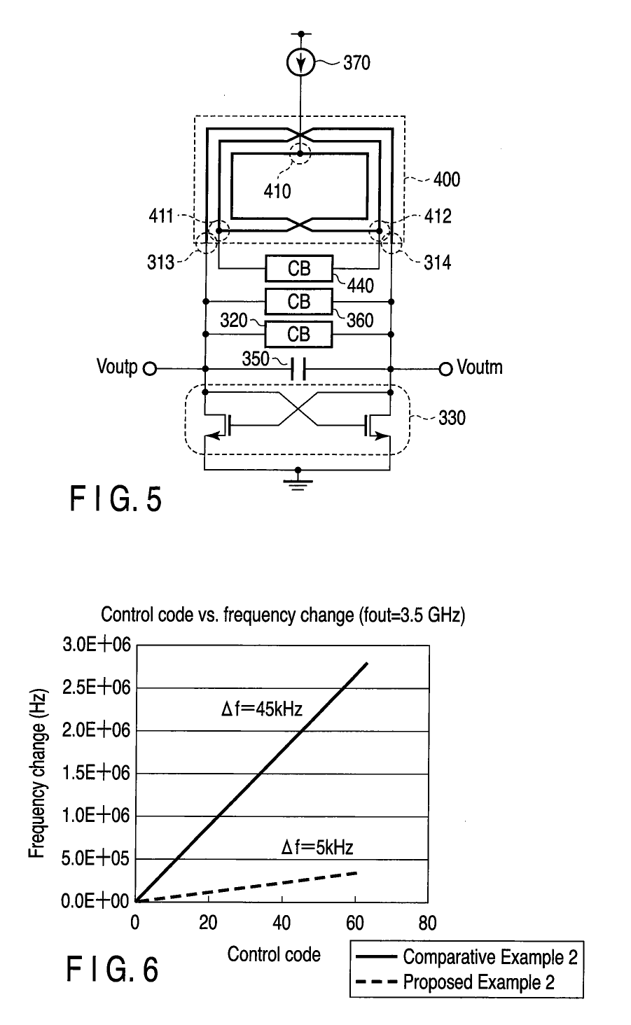

As shown in FIG. 5, in a digitally controlled oscillator according to a second embodiment of the present invention, the differential inductor 300 and the fine tuning variable capacitor bank 340 in the above-described digitally controlled oscillator shown in FIG. 3 are replaced with a differential inductor 400 and a fine tuning variable capacitor bank 440, respectively. In the descriptions that follow, the same components of FIG. 5 as those of FIG. 3 will be denoted by the same reference numerals and different components will be mostly discussed.

The number of turns of the differential inductor 400 is 2.75. The differential inductor 400 has a positive terminal 313 and a negative terminal 314 and a center tap 310 at an approximate center between the positive terminal 313 and the negative terminal 314. Further, the differential inductor 400 has a contact point 411 in a position which internally divides the center tap 310 and the positive terminal 313 into an approximate ratio of 5:6, and a contact point 412 in a position which internally divides the center tap 310 and the negative terminal 314 into an approximate ratio of 5:6.

The positive terminal 313 of the differential inductor 400 is connected to a positive-phase output terminal Voutp, and the negative terminal 314 is connected to a negative-phase output terminal Voutm. Further, a coarse tuning variable capacitor bank 320, a negative resistor 330, a constant capacitor 350 and a middle variable capacitor bank 360 are connected in parallel to each of the positive terminal 313 and the negative terminal 314 of the differential inductor 400. The fine tuning variable capacitor bank 440, which will be described later, is connected between the contact point 411 and the contact point 412 in the differential inductor 400. The center tap 310 in the differential inductor 400 is connected to a bias current source 370.

The fine tuning variable capacitor bank 440 is connected between the contact point 411 provided between the positive terminal 313 and the center tap 310 of the differential inductor 400 and the contact point 412 provided between the negative terminal 314 and the center tap 310, as described above. The fine tuning variable capacitor bank 440 is provided to finely tune the oscillation frequency of the DCO of FIG. 5, and its capacitance is controlled by digital control codes. In the DCO of FIG. 5, by connecting the fine tuning variable capacitor bank 440 between the contact point 411 and the contact point 412, instead of between the positive terminal 313 and the negative terminal 314 of the differential inductor 400, the effect caused by the fine tuning variable capacitor bank 440 on the oscillation frequency can be relatively small, and the capacitance resolution of the fine tuning variable capacitor bank 440 can be substantially improved. The fine tuning variable capacitor bank 440 is fabricated by connecting in parallel a plurality of variable capacitors using gate capacitors of MOS transistors, as shown in FIG. 13A, for example, and changes the overall capacitance by switching the capacitance of each of the variable capacitors between two values by digital control codes.

In order to reduce the effect caused by parasitic elements generated in line which connects the differential inductor 400 and the fine tuning capacitor bank 440 on the fine tuning capacitor bank 440, the length of the line should preferably be made as small as possible. The fine tuning variable capacitor is therefore arranged being interposed between the differential inductor 400 and the middle variable capacitor bank 360, as shown in FIG. 5. Further, the line shape between one end of the fine tuning variable capacitor bank 440 and the contact point 411 of the differential inductor 400 and the line shape between the other end of the fine tuning variable capacitor 440 and the contact point 412 of the differential inductor 400 should preferably be symmetrical.

Next, the frequency resolution of the DCO shown in FIG. 5 will be described below, with reference to the graph shown in FIG. 6. In FIG. 6, the DCO of FIG. 5 is referred to as Proposed Example 2, and the DCO having the same configuration as the DCO of FIG. 5 except for the change of the connection position of the fine tuning variable capacitor bank 440 from the position between the contact point 411 and the contact point 412 of the differential inductor 400 to the position between the positive terminal 313 and the negative terminal 314 is referred to as Comparative Example 2. Each of the variable capacitor banks forming the DCO of each of Proposed Example 2 and Comparative Example 2 is controlled by digital control codes of 6 bits (0-63). FIG. 6 illustrates frequency change of the DCO of each of the Proposed Example 2 and the Comparative Example 2 with reference of the oscillation frequency fout of 3.5 GHz versus change of the digital control codes. In FIG. 6, the frequency change of the oscillation frequency fout of the DCO of Proposed Example 2 is denoted by the dashed line, and the frequency change of the oscillation frequency fout of the DCO of Comparative Example 2 is denoted by the solid line.

As clear from FIG. 6, the DCO of Proposed Example 2 has a higher frequency resolution Δf than the DCO of Comparative Example 2. More specifically, while the frequency resolution Δf of the DCO of Comparative Example 2 is 45 kHz, the frequency resolution Δf of the DCO of Proposed Example 2 is 5 kHz. The frequency change range of the oscillation frequency of the DCO of the Comparative Example 2 is approximately 2.9 MHz (=64×45 kHz), and the frequency change range of the oscillation frequency of the DCO of the Proposed Example 2 is approximately 0.3 MHz (=64×5 kHz).

As described above, the DCO according to the present embodiment is arranged such that the fine tuning variable capacitor bank is interposed between the differential inductor and the middle variable capacitor bank. According to the DCO of the present embodiment, it is therefore possible to make the line between the fine tuning variable capacitor bank and the differential inductor short, and thereby the effect caused by the parasitic elements generated in the line on the fine tuning variable capacitor bank can be reduced.

### Third Embodiment

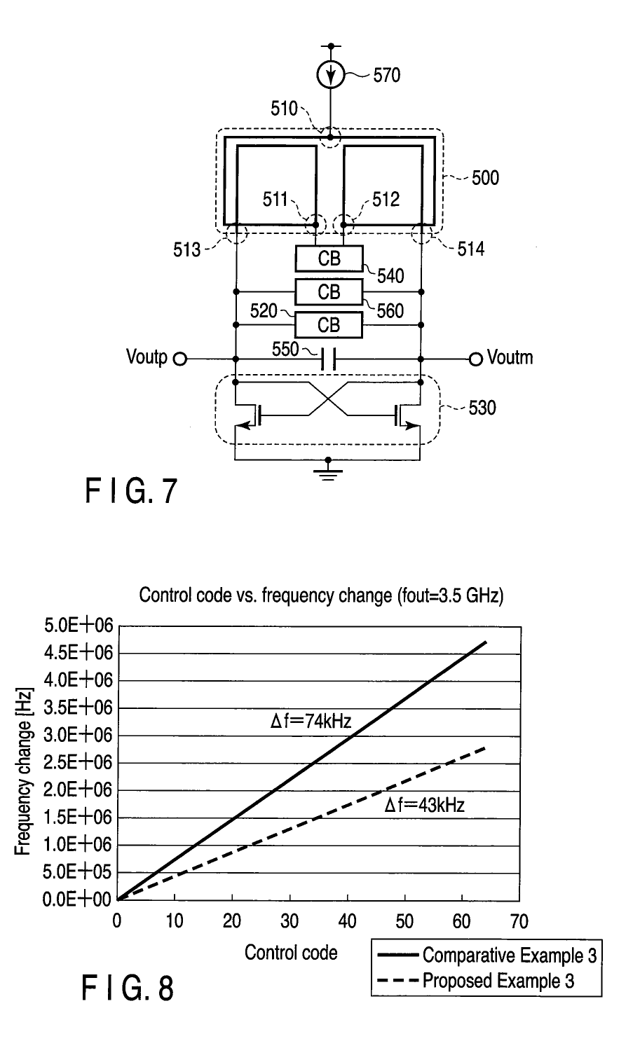

As shown in FIG. 7, a digitally controlled oscillator according to a third embodiment of the present invention includes an inductor pair 500, a coarse tuning variable capacitor bank 520, a negative resistor 530, a fine tuning variable capacitor bank 540, a constant capacitor 550, a middle variable capacitor bank 560, and a bias current source 570.

The inductor pair 500 has a common terminal 510 configured by shorting one ends of two single-phase inductors, the number of turns of which is 1.5. The other ends of the two single-phase inductors form one terminal 513 and the other terminal 514 of the inductor pair 500. Assume that the two single-phase inductors have substantially similar characteristics. The inductor pair 500 has a contact point 511 in a position which internally divides the common terminal 510 and the one end 513 into approximately equal two parts, and a contact point 512 in a position which internally divides the common terminal 510 and the other terminal 514 into approximately equal two parts.

The one end 513 of the inductor pair 500 is connected to a positive-phase output terminal Voutp and the other end 514 is connected to a negative-phase output terminal Voutm. The coarse tuning variable capacitor bank 520, the negative resistor 530, the constant capacitor 550, and the middle variable capacitor bank 560 are connected in parallel to the one end 513 of the inductor pair 500 and the other end 514. The fine tuning variable capacitor bank 540, which will be described below, is connected between the contact point 511 and the contact point 512 in the inductor pair 500. The common terminal 510 in the inductor pair 500 is connected to the bias current source 570.

The coarse tuning variable capacitor bank 520 is provided to coarsely tune the oscillation frequency of the DCO of FIG. 5, and its capacitance is controlled by digital control codes. The coarse tuning variable capacitor bank 520 is fabricated by connecting in parallel a plurality of variable capacitors formed of capacitors connected to switches, and changes the overall capacitance by switching the capacitance of each of the variable capacitors between two values (on/off) by controlling on/off of each of the switches by digital control codes.

The negative resistor 530 compensates for loss made by an LC circuit, that is, loss made by the inductor pair 500, the coarse tuning variable capacitor bank 520, the fine tuning variable capacitor bank 540, and the middle variable capacitor bank 560, and maintains oscillation of the DCO of FIG. 7. The negative resistor 530 is formed of a N-type MOS transistor pair or a P-type MOS transistor pair. More specifically, a negative resistor 530 is fabricated by shorting one drain terminal and the other gate terminal in a common-source MOS transistor pair. The constant capacitor 550 causes a strong effect on the oscillation frequency of the DCO of FIG. 7.

The fine tuning variable capacitor bank 540 is connected between the contact point 511 provided between one end 513 of the inductor pair 500 and the common terminal 510 and the contact point 512 provided between the other terminal 514 and the common terminal 510, as described above. The fine tuning variable capacitor bank 540 is provided to finely tune the oscillation frequency of the DCO of FIG. 7, and its capacitance is controlled by digital control codes. In the DCO of FIG. 7, by connecting the fine tuning variable capacitor bank 540 between the contact point 511 and the contact point 512 instead of between the one end 513 and the other end 514 of the inductor pair, the effect caused by the fine tuning variable capacitor bank 540 on the oscillation frequency can be made relatively small, and the capacitance resolution of the fine tuning variable capacitor bank 540 can be substantially improved. The fine tuning variable capacitor bank 540 is fabricated by connecting in parallel a plurality of variable capacitors using gate capacitors of MOS transistors, as shown in FIG. 13A, for example, and changes the overall capacitance by switching the capacitance of each of the variable capacitors between two values by means of digital control codes.

In order to reduce the effect caused by parasitic elements generated in line for connecting the inductor pair 500 and the fine tuning capacitor bank 540, the length of the line should preferably be made as small as possible. As shown in FIG. 7, the fine tuning variable capacitor bank 540 is therefore arranged being interposed between the inductor pair 500 and the middle variable capacitor bank 560. Further, the line shape between one end of the fine tuning variable capacitor bank 540 and the contact point 511 of the inductor pair 500 and the line shape between the other end of the fine tuning variable capacitor 540 and the contact point 512 of the inductor pair 500 should preferably be symmetrical.

The middle variable capacitor bank 560 is provided to adjust the oscillation frequency of the DCO of FIG. 7, and its capacitance is controlled by digital control codes. The capacitance resolution of the middle variable capacitor bank 560 is higher than that of the coarse tuning variable capacitor bank 520 and lower than that of the fine tuning variable capacitor bank 540. That is, the middle variable capacitor bank 560 is provided to compensate for a gap between the range of oscillating frequencies adjusted by the coarse tuning variable capacitor bank 520 and the range of oscillating frequencies adjusted by the fine tuning variable capacitor bank 540. The middle variable capacitor bank 560 is fabricated by connecting in parallel a plurality of variable capacitors using gate capacitors of MOS transistors, as shown in FIG. 13A, for example, and changes the overall capacitance by switching the capacitance of each of the variable capacitors between two values by means of digital control codes.

Hereinafter, the frequency resolution of the DCO of FIG. 7 will be described with reference to the graph shown in FIG. 8. In FIG. 8, the DCO of FIG. 7 is referred to as Proposed Example 3, and the DCO, which has the same configuration as that of the DCO of FIG. 7 except for the change of the connection position of the fine tuning variable capacitor bank 540 from the position between the contact point 511 and the contact point 512 of the inductor pair 500 to the position between the one terminal 513 and the other terminal 514, is referred to as Comparative Example 3. The variable capacitor bank forming the DCO of each of Proposed Example 3 and Comparative Example 3 is controlled by digital control codes of 6 bits (0-63). FIG. 8 shows frequency change of the DCO of each of Proposed Example 3 and Comparative Example 3 with reference to the oscillation frequency of 3.5 GHz versus change of the digital control codes. In FIG. 8, the frequency change of the oscillation frequency fout of the DCO of Proposed Example 3 is denoted by the dashed line, and the frequency change of the oscillation frequency fout of the DCO of Comparative Example 3 is denoted by the solid line.

As clear from FIG. 8, the DCO of Proposed Example 3 has a higher frequency resolution Δf than the DCO of Comparative Example 3. More specifically, while the frequency resolution Δf of the DCO of the Comparative Example 3 is 74 kHz, the frequency resolution Δf of the DCO of the Proposed Example 3 is 43 kHz. The frequency change range of the oscillation frequency of the DCO of Comparative Example 3 is approximately 4.7 MHz (=64×74 kHz), and the frequency change range of the oscillation frequency of the DCO of the Proposed Example 3 is approximately 2.8 MHz (=64×43 kHz).

As described above, the DCO according to the present embodiment is arranged such that the fine tuning variable capacitor bank is interposed between the inductor pair and the middle variable capacitor bank. According to the DCO of the present embodiment, it is therefore possible to make the line between the fine tuning variable capacitor bank and the inductor pair small, and thereby the effect caused by parasitic elements generated in the line on the fine tuning variable capacitor bank can be reduced.

### Fourth Embodiment

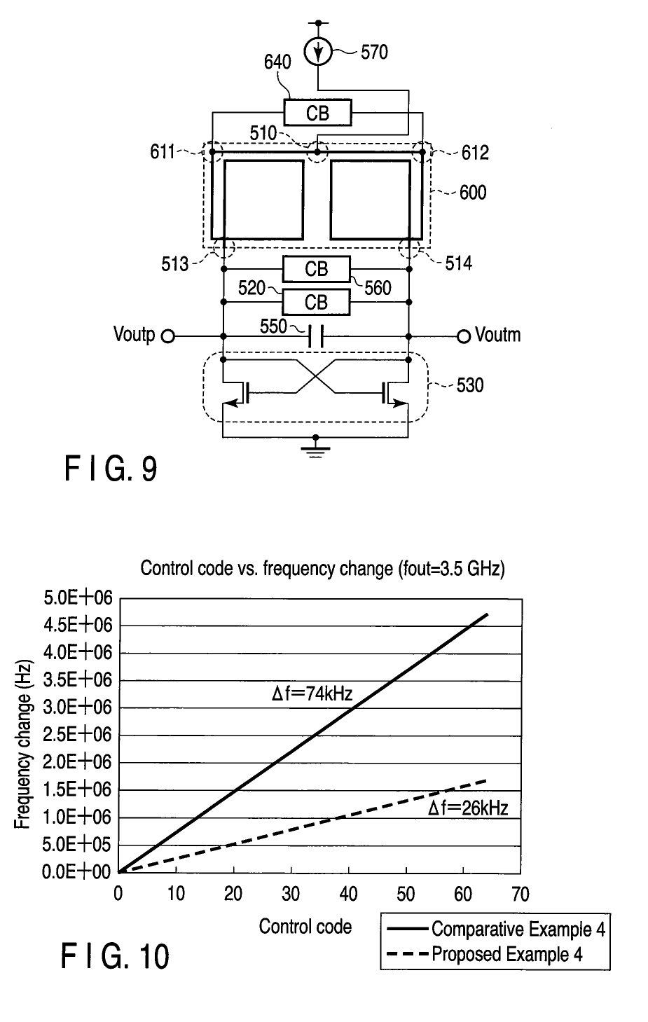

As shown in FIG. 9, in a digitally controlled oscillator according to a fourth embodiment of the present invention, the inductor pair 500 and the fine tuning variable capacitor bank 540 of the above-described digitally controlled oscillator shown in FIG. 7 will be replaced with the inductor pair 600 and the fine tuning variable capacitor bank 640, respectively. In the descriptions that follow, the components of FIG. 9 having the same configurations as those of FIG. 7 will be denoted by the same reference numerals, and different components will be mostly discussed.

The inductor pair 600 has a common terminal 510 configured by shorting one terminals of two single-phase inductors, the number of turns of which is 1.5. Further, the other ends of the two single-phase inductors form one terminal 513 and the other terminal 514 of the inductor pair 600. The two single-phase inductors have substantially similar characteristics. The inductor pair 600 has a contact point 611 in a position which internally divides the common terminal 510 and the one terminal 513 into an approximate rate of 1:5, and a contact point 612 in a position which internally divides the common terminal 510 and the other terminal 514 into an approximate rate of 1:5.

The one end 513 of the inductor pair 600 is connected to a positive-phase output terminal Voutp, and the other end 514 is connected to a negative-phase output terminal Voutm. Further, the coarse tuning variable capacitor bank 520, the negative resistor 530, the constant capacitor 550, and the middle variable capacitor bank 560 are connected in parallel to the one end 513 and the other end 514 of the inductor pair 600. A fine tuning variable capacitor bank 640, which will be described below, is connected between the contact point 611 and the contact point 612 in the inductor pair 600. The common terminal 510 in the inductor pair 600 is connected to a bias current source 570.

The fine tuning variable capacitor bank 640 is connected between the contact point 611 provided between the one terminal 513 and the common terminal 510 of the inductor pair 600, and the contact point 612 between the other terminal 514 and the common terminal 510. The fine tuning variable capacitor bank 640 is provided to finely tune the oscillation frequency of the DCO of FIG. 9, and its capacitance is controlled by digital control codes. In the DCO of FIG. 9, by connecting the fine tuning variable capacitor bank 640 between the contact point 611 and the contact point 612 instead of the position between the one terminal 513 and the other terminal 514 of the inductor pair 600, the effect caused by the fine tuning variable capacitor bank 640 on the oscillation frequency is made relatively small, and thereby the capacitance resolution of the fine tuning variable capacitor bank 640 is substantially improved. The fine tuning variable capacitor bank 640 is fabricated by connecting in parallel a plurality of variable capacitors using gate capacitors of MOS transistors, as shown in FIG. 13A, for example, and changes the overall capacitance by switching the capacitance of each of the variable capacitors between two values by digital control codes.

In order to reduce the effect caused by parasitic elements generated in line which connects the inductor pair 600 and the fine tuning variable capacitor bank 640, the length of the line should desirably be made as small as possible. Therefore, as shown in FIG. 9, the inductor pair 600 is arranged being interposed between the fine tuning variable capacitor bank 640 and the middle variable capacitor bank 560. Further, the line shape between one end of the fine tuning variable capacitor bank 640 and the contact point 611 of the inductor pair 600 and the line shape between the other end of the fine tuning variable capacitor 640 and the contact point 612 of the inductor pair 600 should desirably be symmetrical.

Hereinafter, the frequency resolution of the DCO of FIG. 9 will be described with reference to the graph shown in FIG. 10. In FIG. 10, the DCO of FIG. 9 is referred to as Proposed Example 4, and the DCO having the same configuration as the DCO of FIG. 9 except for the change of the connection position of the fine tuning variable capacitor bank 640 from the position between the contact point 611 and the contact point 612 of the inductor pair 600 to the position between one terminal 513 and the other terminal 514 is referred to as Comparative Example 4. A variable capacitor bank forming the DCO of each of Proposed Example 4 and Comparative Example 4 is controlled by digital control codes of 6 bits (0-63). FIG. 10 denotes frequency change of the DCO of each of Proposed Example 4 and Comparative Example 4 with reference to the oscillation frequency fout of 3.5 GHz versus change of digital control codes. In FIG. 10, the frequency change of the oscillation frequency fout of the DCO of the Proposed Example 4 is denoted by the dashed line, and the frequency change of the oscillation frequency fout of the DCO of Comparative Example 4 is denoted by the solid line.

As clear from FIG. 10, the DCO of the Proposed Example 4 has a higher frequency resolution Δf than the DCO of Comparative Example 4. More specifically, while the frequency resolution Δf of the DCO of Comparative Example 4 is 74 kHz, the frequency resolution Δf of the DCO of the Proposed Example 4 is 26 kHz. The frequency change range of the oscillation frequency of the DCO of Comparative Example 4 is approximately 4.7 MHz (=64×74 kHz), and the frequency change range of the oscillation frequency of the DCO of the Proposed Example 3 is approximately 1.7 MHz (=64×26 kHz).

As described above, the DCO of the present embodiment is arranged such that an inductor pair is interposed between the fine tuning variable capacitor bank and the middle variable capacitor bank. According to the DCO of the present embodiment, it is therefore possible to make the line between the fine tuning variable capacitor bank and the inductor pair short, and thereby the effect caused by parasitic elements generated in the line on the fine tuning variable capacitor bank can be reduced.

### Fifth Embodiment

As shown in FIG. 11, in a digitally controlled oscillator according to a fifth embodiment of the present invention, only the arrangement of the fine tuning variable capacitor bank 540 of the above-described digitally controlled oscillator shown in FIG. 7 is changed. In the descriptions that follow, the components of FIG. 11 having the same configurations as those of FIG. 7 will be denoted by the same reference numerals, and different components will mostly be discussed.

As described above, the fine tuning variable capacitor bank 540 should preferably be arranged in a position close to the inductor pair 500, compared to the coarse tuning variable capacitor bank 520 and the middle variable capacitor bank 560. The fine tuning variable capacitor bank 540 is therefore arranged being interposed between two single-phase inductors forming the inductor pair 500, as shown in FIG. 11. Further, the line shape between one end of the fine tuning variable capacitor bank 540 and the contact point 511 of the inductor pair 500 and the line shape between the other end of the fine tuning variable capacitor 540 and the contact point 512 of the inductor pair 500 should preferably be symmetrical.

In the DCO of FIG. 11, since the connection position of each of both ends of the fine tuning variable capacitor bank 540 is the same as that of the DCO of FIG. 7, the same frequency resolution as that of the DCO of FIG. 7 is exhibited, if the effect caused by parasitic elements generated between the both ends of the fine tuning variable capacitor bank 540 and the contact points 511 and 512 of the inductor pair 500 is not considered.

As described above, the DCO according to the embodiment of the present embodiment is arranged such that the fine tuning variable capacitor bank is interposed between the inductor pair. According to the DCO of the present embodiment, it is therefore possible to make the line between the fine tuning variable capacitor bank and the inductor pair short, and the effect caused by parasitic elements generated in the line on the fine tuning variable capacitor bank can be reduced.

### Sixth Embodiment

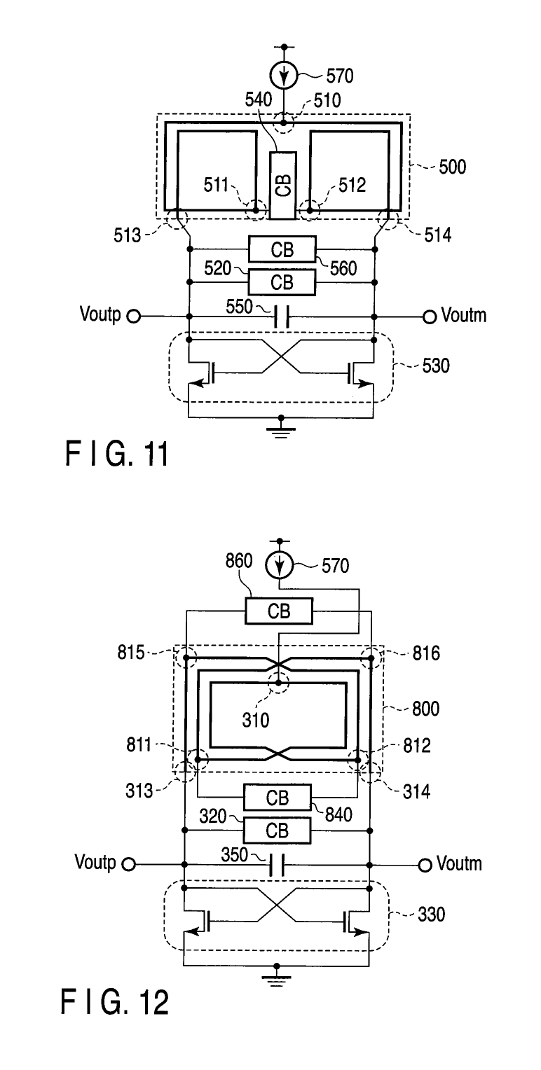

As shown in FIG. 12, in a digitally controlled oscillator according to a sixth embodiment of the present invention, the differential inductor 300, the fine tuning variable capacitor bank 340, and the middle variable capacitor bank 360 of the above-described digitally controlled oscillator shown in FIG. 3 are replaced with a differential inductor 800, a fine tuning variable capacitor bank 840, and a middle variable capacitor bank 860, respectively. In the descriptions that follow, the components of FIG. 12 same as those of FIG. 3 will be denoted by the same reference numerals, and different components will be mostly discussed about.

The number of turns of the differential inductor 800 is 2.75. The differential inductor 800 has a positive terminal 313 and a negative terminal 314, and has a center tap 310 at the approximate center between the positive terminal 313 and the negative terminal 314. Further, the differential inductor 800 has a contact point 811 in a position which internally divides the center tap 310 and the positive terminal 313 into approximately 5:6, and a contact point 812 in a position which internally divides the center tap 310 and the negative terminal 314 into approximately 5:6. Further, the differential inductor 800 has a contact point 815 in a position which internally divides the center tap 310 and the positive terminal 313 into an approximate rate of 9:2, and a contact point 816 in a position which internally divides the center tap 310 and the negative terminal 314 into approximately 9:2.

The positive terminal 313 of the differential inductor 800 is connected to a positive-phase output terminal Voutp, and the negative terminal 314 is connected to a negative-phase output terminal Voutm. Further, the coarse tuning variable capacitor bank 320, the negative resistor 330, and the constant capacitor 350 are connected in parallel to the positive terminal 313 and the negative terminal 314 of the differential inductor 800. A fine tuning variable capacitor bank 840, which will be described below, is connected between the contact point 811 and the contact point 812 in the differential inductor 800. A middle variable capacitor bank 860, which will be described below, is connected between the contact point 815 and the contact point 816 in the differential inductor 800. The contact point 811 and the contact point 812 should preferably be provided close to the center tap 310, as compared to the contact point 815 and the contact point 816. The center tap 310 in the differential inductor 800 is connected to a bias current source 370.

The fine tuning variable capacitor bank 840 is connected between the contact point 811 provided between the positive terminal 313 of the differential inductor 800 and the center tap 310, and the contact point 812 provided between the negative terminal 314 and the center tap 310, as described above. The fine tuning variable capacitor bank 840 is provided to finely tune the oscillation frequency of the DCO of FIG. 12, and its capacitance is controlled by digital control codes. In the DCO of FIG. 12, by connecting the fine tuning variable capacitor bank 840 between the contact point 811 and the contact point 812, instead of between the positive terminal 313 and the negative terminal 314 of the differential inductor 800, the effect caused by the fine tuning variable capacitor bank 840 on the oscillation frequency can be made relatively small, and the capacitance resolution of the fine tuning variable capacitor bank 840 is substantially improved. The fine tuning variable capacitor bank 840 is fabricated by connecting in parallel a plurality of variable capacitors using gate capacitors of MOS transistors, as shown in FIG. 13A, for example, and changes the overall capacitance by switching the capacitance of each of the variable capacitors between two values by means of digital control codes.

The middle variable capacitor bank 860 is connected between the contact point 815 provided between the positive terminal 313 and the center tap 310 of the differential inductor 800 and the contact point 816 provided between the negative terminal 314 and the center tap 310, as described above. The middle variable capacitor bank 860 is provided to adjust the oscillation frequency of the DCO of FIG. 12, and its capacitance is controlled by digital control codes. The capacitance resolution of the middle variable capacitor bank 860 is higher than the coarse tuning variable capacitor bank 320 and lower than the fine tuning variable capacitor bank 840. That is, the middle variable capacitor bank 860 is provided to compensate for a gap between the range of oscillating frequencies adjusted by the coarse tuning variable capacitor bank 320 and the range of oscillating frequencies adjusted by the fine tuning variable capacitor bank 840. In the DCO of FIG. 12, the middle variable capacitor bank 860 is connected between the contact point 815 and the contact point 816, instead of between the positive terminal 313 and the negative terminal 314 of the differential inductor 800, and thereby the effect caused by the middle variable capacitor bank 860 on the oscillation frequency is made relatively small, and the capacitance resolution of the middle variable capacitor bank 860 is substantially improved. The middle variable capacitor bank 860 is fabricated by connecting in parallel a plurality of variable capacitors using gate capacitors of MOS transistors, as shown in FIG. 13A, for example. The overall capacitance is changed by switching the capacitance of each of the variable capacitors by digital control codes.

In order to reduce the effect caused by parasitic elements generated in line which connects the differential inductor 800 and the fine tuning capacitor bank 840 and the middle variable capacitor bank 860 on the fine tuning variable capacitor bank 840 and the middle variable capacitor bank 860, the length of the line should preferably be made as small as possible. The differential inductor 800 is therefore arranged being interposed between the fine tuning variable capacitor bank 840 and the middle variable capacitor bank 860, as shown in FIG. 12. Further, the line shape between one end of the fine tuning variable capacitor bank 840 and the contact point 811 of the differential inductor 800 and the line shape between the other end of the fine tuning variable capacitor 840 and the contact point 812 of the differential inductor 800 should preferably be symmetrical. Moreover, the line shape between one end of the middle variable capacitor bank 860 and the contact point 815 of the differential inductor 800 and the line shape between the other end of the middle variable capacitor bank 860 and the contact point 816 of the differential inductor 800 should preferably be symmetrical.

As described above, the digitally controlled oscillator according to the present embodiment allows the middle variable capacitor bank to be connected between the two contact points provided between the positive and negative terminals and the center tap, instead of between a positive terminal and a negative terminal of a differential inductor. According to the DCO of the present embodiment, it is therefore possible to improve flexibility for setting of capacitance resolution of the middle variable capacitor bank.

### Seventh Embodiment

As shown in FIG. 14, a digital phase locked loop circuit according to a seventh embodiment of the present invention includes a DCO 900, a frequency divider 901, a reference signal generator 902, a counter 903, a digital phase detector 904, a differentiator 905, a digital phase comparator 906, a digital loop filter 907, a variable gain circuit 908, and a control circuit 909.

The DCO 900 is a DCO according to one of the first to sixth embodiments. The DCO 900 includes a fine tuning variable capacitor bank, a middle variable capacitor bank, and a coarse tuning variable capacitor bank. The capacitance of each of the fine tuning variable capacitor bank, the middle variable capacitor bank, and the coarse tuning variable capacitor bank are controlled by control codes Cont1, Cont2, and Cont3, respectively.

The frequency divider 901 divides the frequency (oscillation frequency) of an output signal from the DCO900 at a predetermined frequency division ratio (such as ½), and inputs a frequency division signal to the counter 903 and the digital phase detector 904. The reference signal generator 902 generates a reference signal to be phase-synchronized by the phase locked loop circuit of FIG. 14, and inputs the reference signal to the counter 903 and the digital phase detector 904.

The counter 903 counts the number of cycles of a frequency division signal in a cycle of the reference signal, and inputs the counted value to the digital phase comparator 906. The digital phase detector 904 inputs a digital value indicating a phase difference between the frequency division signal and the reference signal to the differentiator 905. The differentiator 905 differentiates a digital value from the digital phase detector 904 and inputs the differentiated digital value to the digital phase comparator 906.

Assuming that the output digital value of the counter 903 is an integral number part, and an output digital value of the differentiator 905 is a decimal number part, a digital code indicating the frequency ratio of a frequency division signal to the reference signal can be obtained. The digital phase comparator 906 compares the frequency control code with a digital code indicating the frequency ratio. When the digital phase locked loop circuit starts operation, the output of the digital phase comparator 906 is input to the control circuit 909, and the output frequency is coarsely adjusted (Coarse tuning mode). After the coarse tuning mode, an output of the digital phase comparator 906 is input to the loop filter 907, and the output frequency is finely adjusted (fine tuning mode).

The digital loop filter 907 performs a filter processing on a digital code input from the digital phase comparator 907, and inputs the digital code to a variable gain circuit 908. The variable gain circuit 908 adjusts the gain of the digital code input from the digital loop filter 907 and inputs the adjusted gain as a digital control code Cont1 to the DCO 900. The control circuit 909 generates digital control codes Cont2 and Cont3 from the digital codes input from the digital phase comparator 907, and inputs the digital control codes Cont2 and Cont3 to the DCO900.

As described above, the phase locked loop circuit according to the present embodiment uses the DCO according to one of the first to sixth embodiments. According to the phase locked loop circuit of the present embodiment, it is therefore possible to finely control the oscillation frequency of the DCO almost linearly, and a desired output signal can be obtained.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

For example, a variable capacitor using a gate capacitor of a MOS transistor has been exemplified as a variable capacitor forming a variable capacitor bank of a DCO of each of the embodiments, but can be replaced with a variable capacitor using a base capacitor of a bipolar transistor. Further, the negative resistor has been configured by a MOS transistor pair, but may be configured by a bipolar transistor pair. A bias may be applied to the inductor from the ground side as well as the power source side. Moreover, the inductor in the DCO may be replaced with other elements having an inductor such as a transmission line.

Needless to say, the present invention can be similarly embodied even with various modifications within the range of not departing from the spirit of the invention.

What is claimed is:

1. A digitally controlled oscillator comprising:
a differential inductor including a positive terminal which outputs a positive-phase oscillation signal, a negative terminal which outputs a negative-phase oscillation signal, and a center tap, and including a first contact point in an arbitrary position between the positive terminal and the center tap, and a second contact point in a position corresponding to the first contact point between the negative terminal and the center tap;
a first variable capacitor bank connected between the positive terminal and the negative terminal and including a plurality of first variable capacitors which switch capacitance between two values by means of a first digital control code;
a second variable capacitor bank connected between the first contact point and the second contact point and including a plurality of second variable capacitors which switch capacitance between two values by means of a second digital control code; and
a negative resistor connected between the positive terminal and the negative terminal.

2. The oscillator according to claim 1, wherein
a shape of a first line which connects one end of the second variable capacitor bank and the first contact point and a shape of a second line which connects the other end of the second variable capacitor bank and the second contact point are approximately symmetrical,
and the differential inductor is arranged being interposed between the first variable capacitor bank and the second variable capacitor bank.

3. The oscillator according to claim 1, wherein
a shape of a first line which connects one end of the second variable capacitor bank and the first contact point and a shape of a second line which connects the other end of the second variable capacitor bank and the second contact point are approximately symmetrical,
and the second capacitor bank is arranged being interposed between the differential inductor and the first variable capacitor bank.

4. The oscillator according to claim 1, wherein a capacitance change range of each of the plurality of second variable capacitors is smaller than a capacitance change range of each of the plurality of first variable capacitors.

5. A digitally controlled oscillator comprising:
an inductor pair formed by shorting one end of a first inductor and one end of a second inductor, configured to output a positive-phase oscillation signal from the other end of the first inductor and output a negative-phase oscillation signal from the other end of the second inductor, and including a first contact point in an arbitrary position of the first inductor and a second contact point in a position corresponding to the first contact point of the second inductor;
a first variable capacitor bank connected between the other end of the first inductor and the other end of the second inductor and including a plurality of first variable capacitors which switch capacitance between two values by a first digital control code;
a second variable capacitor bank connected between the first contact point and the second contact point and including a plurality of second variable capacitors which switch capacitance between two values by a second control code; and
a negative resistor connected between the other end of the first inductor and the other end of the second inductor.

6. The oscillator according to claim 5, wherein
a shape of a first line which connects one end of the second variable capacitor bank and the first contact point and a shape of a second line which connects the other end of the second variable capacitor bank and the second contact point are approximately symmetrical, and
the second variable capacitor bank is arranged being interposed between the first variable capacitor bank and the inductor pair.

7. The oscillator according to claim 5, wherein
a shape of a first line which connects one end of the second variable capacitor bank and the first contact point and a shape of a second line which connects the other end of the second variable capacitor bank and the second contact point are approximately symmetrical, and
the inductor pair is arranged being interposed between the first variable capacitor bank and the second variable capacitor bank.

8. The oscillator according to claim 5, wherein
a shape of a first line which connects one end of the second variable capacitor bank and the first contact point and a shape of a second line which connects the other end of the second variable capacitor bank and the second contact point are approximately symmetrical, and
the second variable capacitor bank is arranged being interposed between the first inductor and the second inductor.

9. The oscillator according to claim 5, wherein a capacitance change range of each of the plurality of second variable capacitors is smaller than a capacitance change range of each of the plurality of first variable capacitors.

10. A phase locked loop circuit comprising:
the oscillator according to claim 1;
a frequency divider configured to divide a frequency of an output signal from the oscillator to obtain a frequency division signal;
a first generating unit configured to generate the first digital control code such that a frequency difference between the frequency division signal and a desired signal is reduced; and
a second generating unit configured to generate the second digital control code such that the phase difference between the frequency division signal and the desired signal is reduced.
